(19) United States
(12) Patent Application Publication
(10) Pub. No.: US 2009/0021924 A1
(43) Pub. Date: Jan. 22, 2009

(54) GUIDE MEMBER, CONNECTION BOARD HAVING GUIDE MEMBER, AND MANUFACTURING METHOD OF GUIDE MEMBER

(75) Inventors: Tetsuharu OGINO, Miyagi-ken (JP); Shuuichi CHIBA, Miyagi-ken (JP); Taiji OKAMOTO, Miyagi-ken (JP); Shin YOSHIDA, Miyagi-ken (JP)

Correspondence Address: BRINKS HOFER GILSON & LIONE, P.O. BOX 10395, CHICAGO, IL, 60610, US

(73) Assignee: Alps Electric Co., Ltd., Tokyo (JP)

(21) Appl. No.: 12/181,698

(22) Filed: Jul. 29, 2008

(30) Foreign Application Priority Data
Jan. 30, 2006 (JP) 2006-020382
Jul. 28, 2006 (JP) 2006-205935
Jan. 29, 2007 (JP) PCT/JP2007/051349

(51) Int. Cl. H05K 7/00; H05K 13/00

(52) U.S. Cl. 361/809; 29/874

(57) ABSTRACT

Object A connection board is provided in which multiple external contacts of an electronic component and multiple spiral contacts on a board are arranged to highly accurately face each other, and the external contacts are actively guided to the spiral contacts, so as to reliably provide individual connections therebetween.

Solving Means A connection board CB includes a relay board 20 having a plurality of spiral contacts 24A, 24B provided on both surfaces of the relay board 20, and a guide member 30 having a plurality of small holes 31 into which the spiral contacts 24A and a plurality of external contacts 2a provided on an electronic component 1 are respectively inserted in both directions. The relay board 20 and the guide member 30 are arranged to face each other. Small holes 31A provided in at least two or more corner portions from among the plurality of small holes 31 have a diameter smaller than a diameter of the residual plurality of small holes 31. When the electronic component 1 is mounted, the external contacts 2a at the corner portions are positioned with the positioning small holes 31A at the corner portions. Hence, the external contacts 2a can be also positioned with respect to the residual small holes 31.

### TECHNICAL FIELD

The present invention relates to a connection board that connects a plurality of contacts provided on an electronic component (semiconductor or the like) to a plurality of corresponding elastic contacts, and more particularly to a guide member that guides the contacts to the elastic contacts, a connection board having the guide member, and a manufacturing method of the guide member.

### BACKGROUND ART

In patent document 1, when elastic contact is to be provided between external contacts formed on a bottom surface of an electronic component such as a semiconductor and spiral contacts provided on an upper surface of a relay board, a protection sheet having a plurality of small holes is interposed between the electronic component and the relay board, so that the external contacts directly contact the spiral contacts via the small holes.

The relay board and the protection sheet are positioned by inserting positioning pins provided on a connection board into positioning holes formed in the relay board and the protection sheet.

Patent Document 1: Japanese Unexamined Patent Application Publication No. 2005-134373 (pages 7 to 8, FIGS. 4A and 4B).

### DISCLOSURE OF INVENTION

### Problems to be Solved by the Invention

In patent document 1, although desirable positioning of the electronic component is not disclosed in patent document 1, the electronic component is generally positioned by using an inner wall, which forms a loading portion of a socket, as a reference, and pressing one of lateral surfaces of the electronic component to the inner wall. However, to employ such a positioning method, external dimensions of the electronic component have to be highly accurate.

Unfortunately, an external accuracy of an actual electronic component is low. Hence, the external contacts cannot highly accurately face the small holes and the spiral contacts even when the electronic component is loaded in the loading portion.

In particular, the protection sheet is provided for preventing the spiral contacts from being deformed and preventing dusts from entering. The protection sheet does not have a function of actively guiding external connection electrodes to spiral contacts.

That is, with the existing configuration, individual connections between the external contacts and the corresponding spiral contacts are not reliably provided.

The present invention is provided to overcome the existing problems, and it is an object of the present invention to provide a connection board including a guide member by which individual external contacts and individual spiral contacts are highly accurately arranged to face each other even when the accuracy of external dimensions of an electronic component is low.

It is another object of the present invention to provide a connection board including a guide member that reliably provides individual connections by actively guiding external contacts to spiral contacts.

It is still another object of the present invention to provide a guide member and a manufacturing method thereof capable of highly accurately forming small holes in the guide member forming a connection board, and manufacturing the guide member with a low cost.

### Means for Solving the Problems

According to the present invention, a connection board includes a relay board having a plurality of spiral contacts provided on both surfaces of the relay board, and a guide member having a plurality of small holes into which the spiral contacts and a plurality of external contacts provided on an electronic component are respectively inserted from both sides of the guide member in a plate-thickness direction, the relay board and the guide member being arranged to face each other. Positioning small holes are arranged in at least two or more corner portions of the guide member together with the plurality of small holes. A diameter of the positioning small holes is formed smaller than a diameter of the residual plurality of small holes.

With the present invention, the individual small holes formed in the guide member and the individual external contacts formed on a connection surface of the electronic component can be highly accurately positioned. Accordingly, the individual spiral contacts provided on the relay board and the individual external contacts formed on the connection surface of the electronic component can be reliably conductively connected to each other via the guide member.

Preferably, in the above configuration, an inclined surface may be formed in at least one of edge portions in the plate-thickness direction of each of the small holes.

With the above means, the individual external contacts formed on the connection surface of the electronic component and the individual spiral contacts provided on the relay board can be actively guided to the small holes at either or both of a front surface and a back surface of the guide member.

According to the present invention, a connection board includes a relay board having a plurality of spiral contacts provided on both surfaces of the relay board, and a guide member having a plurality of small holes into which the spiral contacts and a plurality of external contacts provided on an electronic component are respectively inserted from both sides of the guide member in a plate-thickness direction, the relay board and the guide member being arranged to face each other. A supporting mechanism and a biasing member are provided between the relay board and the guide member. The supporting mechanism supports the guide member and the relay board such that a facing distance therebetween is changeable in a facing direction in which the guide member and the relay board move close to or away from each other. The biasing member biases the relay board and the guide member in the facing direction and allowing the relay board and the guide member to move in a direction orthogonal to the facing direction.

With the present invention, the guide member can be easily positioned with respect to the relay board. Accordingly, the spiral contacts can be easily guided into the small holes.

Preferably, in the above configuration, the biasing member may be a leaf spring including a base portion fixed to a pedestal, an elastic portion extending from the base portion, and a protrusion formed at a tip end of the elastic portion. The leaf spring may be formed at the relay board.

With the above means, the biasing member can be formed of a simple configuration.

In addition, preferably, the guide member may have a recess into which the protrusion is inserted. Further, a width of the recess may be larger than a width of the protrusion, and may be smaller than a width of the base portion.

With the above means, since the protrusion is inserted to the recess, a displacement in a horizontal direction orthogonal to the facing direction between the relay board and the guide member can be prevented.

In addition, preferably, the recess may be a long groove or a long hole having a longitudinal direction parallel to one of sides of the guide member.

With the above means, since the protrusion can move along the long groove or the long hole in the longitudinal direction thereof, if a displacement occurs, the displaced position can be easily restored to a proper position before the occurrence of the displacement.

In addition, preferably, each of the spiral contacts and the leaf spring may be formed in a single manufacturing step.

With the above means, since the biasing member can be highly accurately formed like the spiral contact, the displacement in the horizontal direction of the guide member elastically supported by the relay board can be reduced. Also, since the biasing member and the spiral contact can be formed in the single step, the number of manufacturing steps of the relay board can be reduced.

According to the present invention, a guide member includes a plurality of small holes arrayed therein. Positioning small holes are arranged in at least two or more corner portions together with the plurality of small holes. A diameter of the positioning small holes is smaller than a diameter of the residual plurality of small holes.

With the present invention, individual external contacts formed on a connection surface of an electronic component and the individual small holes formed in the guide member can be highly accurately positioned.

Preferably, in the above configuration, an inclined surface may be formed in at least one of edge portions in the plate-thickness direction of each of the small holes.

With the above means, the individual external contacts and the individual spiral contacts provided on the relay board can be smoothly guided to the small holes.

In addition, a recess is formed near one of sides of the guide member, the recess being a long groove or a long hole having a longitudinal direction parallel to the side.

Further, a plurality of small holes are formed in a main body made of metal, and a frame made of resin is provided on a periphery of the main body.

With the above means, a frame portion which is hardly changed in layout (changed in design) can be commonly used. Accordingly, the design of only the main body can be changed when a change is made in layout thereof. Also, since the main body is made of metal, a processing accuracy of the main body having the plurality of small holes can be increased.

According to the present invention, manufacturing method of a guide member is provided. The guide member including a main body having a plurality of small holes formed therein and a frame for holding a periphery of the main body. The method includes (a) a step of forming a resist layer on a surface of a substrate; (b) a step of forming a pattern of the main body form in the resist layer; (c) a step of forming the main body within the pattern of the main body form remaining in the resist layer; (d) a step of removing the resist layer; (e) a step of applying insulating coating on an entire surface of the main body; and (f) a step of forming the frame on the periphery of the main body.

With the above manufacturing method, the main body having the plurality of small holes and the frame provided on the periphery of the main body can be formed in the separate steps. Accordingly, the main body demanded for a relatively high processing accuracy can be manufactured by a highly accurate manufacturing method, whereas the frame portion which may have a relatively low accuracy can be manufactured by a more simple method.

In addition, since the main body which may be frequently changed in layout and the frame portion which is hardly changed in layout can be formed in the separate steps, even when the main body is changed in layout, the manufacturing cost can be low.

For example, in the step (b), the pattern of the main body form may be formed in the resist layer by covering the resist layer with a predetermined mask, and performing exposing, photosensitizing, and developing.

Alternatively, in the step (b), the pattern of the main body form may be formed by irradiating the resist layer with ultraviolet and etching the pattern of the main body form.

With one of the methods, the main body can be highly accurately formed without a mold.

Also, the step (c) may preferably further include (g) a step of forming a base layer on surfaces of the substrate and the pattern of the main body form; and (h) a step of forming the main body within the pattern of the main body form by plating.

With the above means, the main body having a relatively small plate thickness can be highly accurately formed by developing plating.

In addition, preferably, in the step (e), the insulating coating may be performed by spraying insulating paint.

With the above means, since the insulating paint can be applied in a mist form, the multiple small holes formed in the guide member can be reliably coated with an insulating film.

Accordingly, insulation between ball contacts of the electronic component and the main body of the guide member can be maintained.

In addition, preferably, the step (f) may further include (i) a step of setting the main body within a predetermined mold; (j) a step of injecting melted resin to the periphery of the main body in the mold; (k) a step of setting the melted resin, thereby integrally forming the frame on the periphery of the main body; and (l) a step of removal from the mold.

With the above means, the frame having the predetermined shape can be integrally attached on the periphery of the main body.

### ADVANTAGES

With the present invention, even when the accuracy of the external dimensions of the electronic component is low, the individual external contacts (ball contacts) formed on the connection surface of the electronic component and the individual spiral contacts formed on the relay board can be highly accurately arranged to face each other.

Also, the individual external contacts can reliably contact the individual spiral contacts via the small holes formed in the guide member.

Further, with the present invention, the manufacturing method of the guide member by which the plurality of small holes can be highly accurately formed with a low manufacturing cost can be provided.

### BEST MODES FOR CARRYING OUT THE INVENTION

FIG. 1 is a perspective view showing a socket for holding an electronic component when viewed from above the socket according to an embodiment of the present invention. FIG. 2 is a perspective view showing the socket in FIG. 1 from below the socket. FIG. 3 is a plan view of the socket. FIG. 4 is a cross section showing a configuration of the socket. FIG. 5 is a perspective view showing a relay board and a guide member. FIG. 6 is a plan view of the relay board. FIG. 7 is an enlarged cross section showing a part of the relay board. FIG. 8 is an enlarged plan view partially showing the guide member. FIG. 9 is a perspective view showing a state in which a biasing member of the relay board is inserted into a recess of the guide member. FIGS. 10A to 10C are cross sections for explaining an operation of a connection board, in which A indicates a state immediately after the electronic component is mounted on the guide member, B indicates a state in which the electronic component is moving on the guide member after A, and C indicates a state in which mounting of the electronic component is completed.

A socket 10 shown in FIG. 1 is for holding and fixing an electronic component 1 such as a semiconductor in which multiple external connection electrodes (external contacts) are arranged on a connection surface of the electronic component 1 in, for example, a matrix form (also called lattice form or grid form), or a “square ring” form in plan view. Multiple sockets 10 are provided on a single burn-in board (board) 40. The burn-in board 40 with an electronic component 1 mounted in every socket 10 is loaded in a burn-in test apparatus, and a burn-in test is performed.

External contacts (external connection electrodes) 2 formed on a connection surface 1A of the electronic component 1 may be, for example, land contacts (LGA: land grid array), ball contacts (BGA: ball grid array), or pin contacts (PGA: pin grid array). Hereinafter, description with the use of ball contacts 2a will be given (see FIGS. 4 and 10).

Referring to FIGS. 1 and 2, the socket 10 includes a frame body 10A having a recessed loading portion 11, and a pair of holding mechanisms 12, 12 provided within the frame body 10A. The holding mechanisms 12 include a pair of rotatably supported, left and right arms 12a, 12a, support shafts 12b respectively disposed between tip ends of the one arm 12a and between tip ends of the other arm 12a, pressing members 12c provided rotatably relative to the support shafts 12b, biasing members (not shown) that bias the pair of arms 12a, 12a inward of the loading portion 11, and other components.

Referring to FIG. 1, when both the arms 12a, 12a are lifted upward (Z1 direction) against biasing forces of the biasing members, a facing distance between the pressing member 12c provided at the one arm 12a and the pressing member 12c provided at the other arm 12a is increased, thereby causing the loading portion 11 to become an open state. In the open state, the electronic component 1 such as a semiconductor can be mounted in the loading portion 11 (see FIG. 4).

When lifting forces to both the arms 12a, 12a are released, both the arms 12a, 12a are rotated inward, and an upper surface of the electronic component 1 is pressed downward in the drawing by the pair of pressing members 12c, 12c. Accordingly, the electronic component 1 can be held by and fixed to the loading portion 11.

Referring to FIGS. 1, 3, and other figures, a substantially square opening 11a is formed in a bottom of the loading portion 11 to penetrate therethrough in an vertical direction in the drawings (Z1-Z2 direction). Also, referring to FIGS. 2 and 4, a depressed portion 10B is formed in a back surface of a bottom of the frame body 10A at an outer peripheral portion of the opening 11a. The depressed portion 10B is recessed from the back surface of the bottom in the Z1 direction in the drawings so as to surround the opening 11a. A plurality of bosses 10a protruding in the Z2 direction in the drawings are formed at corner portions of the depressed portion 10B. The bosses 10a each have a leg 10a2 provided near a base end thereof, and a first retainer 10a1 provided near a tip end thereof.

Referring to FIG. 3, positioning corners 14, 14, 14, 14 each having a substantially L-like shape in plan view are provided at four corner portions of the opening 11a. A tapered surface 14a being inclined toward the opening 11a is formed at inner side of each of the positioning corners 14. A guide member 30 shown in FIG. 5 is provided in an area surrounded by the positioning corners 14, 14, 14, 14.

Also, referring to FIGS. 1 and 3, cut portions 11b, 11b are formed near the positioning corners 14, 14 on the Y1 side. The cut portions 11b, 11b each are continuously cut outward into a substantially U-like shape (Y1 direction in FIG. 3) extending from an edge of the opening 11a. A sheet 21 which forms a relay board 20 is provided at the depressed portion 10B so that the sheet 21 partially faces the cut portions 11b, 11b. The relay board 20 and the guide member 30 define a connection board CB of the present invention.

Referring to FIGS. 2 to 4, and other figures, the relay board 20 forming the connection board CB is provided at the back surface of the bottom of the socket 10. In particular, referring to FIGS. 2 and 4, the relay board 20 is fixed within the depressed portion 10B in a positioned manner.

Referring to FIG. 3, the relay board 20 is formed with a base material which is an insulating sheet 21 made of, for example, resin such as polyimide. Referring to FIG. 7, the sheet 21 has multiple through holes 22 regularly made in predetermined numbers of rows and columns in the X and Y directions. In FIG. 3, the through holes 22 are entirely arrayed in a “square ring” form in plan view.

The array form of the multiple through holes 22 depends on an array of the ball contacts (external contacts) 2a formed on the connection surface of the electronic component 1 (semiconductor). Hence, the array form is not limited to the above-described “square ring” form in plan view. For example, if an electronic component 1 (semiconductor) has ball contacts 2a arrayed in a matrix form in plan view, multiple through holes 22 are also arrayed in a matrix form in plan view.

Referring to FIG. 7, a conductive portion 23 is formed on an inner peripheral surface of each of the through holes 22 by copper plating. Connecting portions 23a, 23b exposed to a front surface and a back surface of the sheet 21 are respectively formed at an upper end (end on the Z1 side in the drawing) and a lower end (end on the Z2 side in the drawing) of the conductive portion 23. The connecting portion 23a at the upper end and the connecting portion 23b at the lower end are conductively connected to each other via the conductive portion 23.

Referring to FIG. 7, a conductive portion 23 is formed on an inner peripheral surface of each of the through holes 22 by copper plating. Connecting portions 23a, 23b exposed to a front surface and a back surface of the sheet 21 are respectively formed at an upper end (end on the Z1 side in the drawing) and a lower end (end on the Z2 side in the drawing) of the conductive portion 23. The connecting portion 23a at the upper end and the connecting portion 23b at the lower end are conductively connected to each other via the conductive portion 23.

An upper spiral contact (elastic contact) 24A and a lower spiral contact (elastic contact) 24B are respectively provided at the upper and lower sides of each through hole 22 so as to cover both opening ends of the through hole 22.

The spiral contacts 24A, 24B are formed, for example, by plating nickel or the like on a surface of a conductive material such as copper, to obtain a function of elastic contacts generally having good conductivity and elasticity.

The spiral contacts 24A and 24B have equivalent configurations, and each have a substantially ring-like base portion 24a at an outer peripheral portion thereof. The base portion 24a of the upper spiral contact 24A is connected to the connecting portion 23a at the upper end, and the base portion 24a of the lower spiral contact 24B is connected to the connecting portion 23b at the lower end. Hence, the upper and lower spiral contacts 24A and 24B are conductively connected to each other via the conductive portion 23.

The spiral contacts 24A, 24B each extend from a winding start 24b provided near the base portion 24a toward a winding end 24c provided near a tip end in a spiral manner. The winding end 24c is located substantially at the center of the through hole 22. The spiral contacts 24A, 24B each are molded into a protruding form so as to be gradually away from the sheet 21 as extending from the winding start 24b toward the winding end 24c. Thus, the spiral contacts 24A, 24B are elastically deformable in the vertical direction (Z1-Z2 direction) at both the opening ends of the through hole 22.

Referring to FIGS. 5 and 6, a plurality of leaf springs (biasing members) 25 are provided on the front surface of the sheet 21 forming the relay board 20, in an area outside an area where the plurality of spiral contacts 24A are formed.

The leaf springs 25 are formed by cutting out thin, band-like metal plates. The leaf springs 25 have frame-like base portions 25a and elastic portions 25b, and are directed such that longitudinal directions thereof become parallel to respective sides of the sheet 21.

Each of the leaf springs 25 is configured such that the base portion 25a is fixed on the front surface of the sheet 21, and the elastic portion 25b is formed as a free end rising upward in the drawing (Z1) from the sheet 21. A protrusion 25c, which has a smaller width than that of the elastic portion 25b is formed at a tip end of the free end.

The leaf spring 25 may be formed, for example, by nickel plating whereby an elastic force is applied to a surface of a copper plate. In this case, the leaf spring 25 can be formed simultaneously in a step for forming the spiral contact 24A. In this case, the leaf spring 25 can be formed on the sheet 21 with a high processing accuracy like the spiral contact. Hence, though described later, when the guide member 30 is elastically supported by the leaf springs 25, a displacement of the guide member 30 in a horizontal direction can be reduced. Also, since the spiral contact 24 and the leaf spring 25 can be simultaneously formed in a single manufacturing step, the number of manufacturing steps can be reduced.

Referring to FIG. 5, through holes 26, into which supporting protrusions (supporting mechanisms) 33, described later, are inserted, are formed in corner portions of the sheet 21 forming the relay board 20, and positioning holes 27 are formed near the through holes 26.

Referring to FIGS. 4 and 5, the guide member 30 is provided above the relay board 20 in the Z1 direction in the drawings. The guide member 30 is a flat plate-like member having a substantially square shape, and is formed, for example, by injection molding in which insulating resin is injected into a mold and the resin is integrally molded, or by a manufacturing method, which will be described later.

Referring to FIG. 5, the guide member 30 includes a base 30A made of resin, and a rectangular through hole 30B formed in a center portion of the base 30A.

Also, positioning means including a plurality of small holes 31 is provided, the small holes 31 penetrating through a peripheral area of the through hole 30B in the vertical direction (Z1-Z2 direction in the drawing). The individual small holes 31 are formed respectively for the ball contacts (external contacts) 2a of the electronic component 1 and the through holes 22 of the relay board 20. The small holes 31 are entirely arrayed in a “square ring” form in plan view similarly to the above. It is noted that the form may be others, for example, a matrix form in plan view, depending on an array form of the external contacts 2 formed on the connection surface 1A of the electronic component 1, in a manner similar to the through holes 22 of the relay board 20.

From among the multiple small holes 31 defining the positioning means, four positioning small holes 31A, 31A, 31A, 31A provided at the corner portions have a diameter smaller than that of the residual multiple small holes 31. For example, when the diameter of the ball contacts 2a of the electronic component 1 is 0.6 mm, the diameter of the four positioning small holes 31A is 0.71 mm, and the diameter of the residual multiple small holes 31 is 0.75 mm.

Referring to FIGS. 8, and 10A to 10C, the small holes 31 and the positioning small holes 31A have inclined surfaces 31a, 31b formed at edges of front or back ends (edges at one side in a plate-thickness direction) thereof, more preferably, at edges of both the front and back ends thereof. Thus, in the guide member 30 according to this embodiment, either or both of the ball contacts 2a and the upper spiral contacts 24A can be easily guided into the small holes 31 and the positioning small holes 31A.

Referring to FIG. 5, a plurality of recesses 32 and a plurality of supporting protrusions 33 are formed at an outer peripheral portion of the base 30A. The recesses 32 extend in parallel to respective sides of the outer peripheral portion. The supporting protrusions 33 protrude downward in the drawing (a plurality extending in Z2 direction) from the back surface (surface on the Z2 side) of the base 30A.

The recesses 32 are, for example, band-like long grooves or long holes, and formed at positions corresponding to the leaf springs (biasing members) 25 provided at the relay board 20. A width of the recesses 32 is larger than that of the protrusions 25c of the leaf springs 25, and is smaller than that of the elastic portions 25b.

Hence, when the protrusions 25c are inserted to the recesses 32, shoulders 25d of the elastic portions 25b serving as base portions of the protrusions 25c come into contact with the peripheries of the recesses 32 (back surface of the base 30A). The guide member 30 is elastically supported by the plurality of leaf springs 25 in this manner (see FIGS. 4 and 9).

Dimensions of the base 30A of the guide member 30 in the vertical and horizontal directions (dimensions in the X and Y directions) are respectively slightly smaller than a facing distance between the positioning corners 14, 14 in the X direction and a facing distance between the positioning corners 14, 14 in the Y direction, the corners 14 being provided at the four corner portions of the opening 11a. Hence, when the guide member 30 is loaded within the loading portion 11, the guide member 30 can be loaded within the area surrounded by the positioning corners 14, 14, 14, 14.

When the electronic component 1 is loaded within the loading portion 1, the electronic component 1 can be guided to a proper position within the loading portion 11 along the tapered surfaces 14a of the positioning corners 14.

It is noted that the facing distances between the positioning corners 14, 14 in the X direction, and between the positioning corners 14, 14 in the Y direction contain certain margins to allow the electronic component 1 to move slightly in the X and Y directions within the area surrounded by the positioning corners 14, 14, 14, 14, when the electronic component 1 is loaded within the loading portion 11. The margins in the X and Y directions are provided at the connection surface of the electronic component 1, and are preferably respectively smaller than pitches between the adjacently provided external contacts (ball contacts) 2 in the X and Y directions.

The supporting protrusions 33 are integrally formed on the back surface of the base 30A so as to protrude downward in the Z2 direction in the drawing from the back surface. A length of the supporting protrusions 33 is larger than a rising dimension of the leaf springs 25 in a height direction (Z direction).

To assemble the connection board CB using the above-described relay board 20 and the guide member 30, first, tip ends of the supporting protrusions 33 of the guide member 30 are respectively inserted to the through holes 26 of the relay board 20. At this time, the protrusions 25c of the leaf springs 25 are respectively inserted to the recesses 32 of the guide member 30.

Then, stopper means 33a having a dimension larger than a diameter of the through holes 26 is provided at each of the tip ends of the supporting protrusions 33 at the back surface (Z2 side) of the relay board 20, so that the supporting protrusions 33 are not detached from the through holes 26. The stopper means 33a may be, for example, a configuration in which the tip end of each supporting protrusion 33 is deformed by heating to have the dimension larger than the diameter of each through hole 26, or a configuration in which another member having a dimension larger than the diameter of each through hole 26 is attached to the tip end of each supporting protrusion 33.

As described above, the connection board CB can be formed by integrally assembling the relay board 20 with the guide member 30.

Meanwhile, the diameter of each through hole 26 is larger than the diameter of each supporting protrusion 33. Accordingly, in the connection board CB after the integration, a facing distance between the relay board 20 and the guide member 30 is changeable within the length of the supporting protrusions 33 in a facing direction (Z direction) in which the relay board 20 and the guide member 30 move close to or away from each other.

The length of each supporting protrusion 33 after the assembling as the connection board CB is preferably set such that the facing distance between the relay board 20 and the guide member 30 becomes smaller than the rising dimension of each leaf spring 25 in the height direction (Z direction). In this state, the protrusions 25c of the leaf springs 25 are hardly detached from the recesses 32 of the guide member 30. Accordingly, the condition in which the guide member 30 is elastically supported by the leaf springs 25 can be maintained.

Also, referring to FIG. 10, the protrusion 25c is movable in a longitudinal direction thereof (in a direction indicated by an arrow in FIG. 10) within the recess 32. In particular, the leaf spring 25 having the longitudinal direction parallel to the X direction is allowed to move in the X direction in the XY plane, whereas the leaf spring 25 having the longitudinal direction parallel to the Y direction is allowed to move in the Y direction. Hence, the guide member 30 is movable in horizontal directions (X and Y directions) along a horizontal plane parallel to the XY plane relative to the relay board 20. Accordingly, a relative displacement between the guide member 30 and the relay board 20 in the horizontal directions can be corrected. Therefore, the multiple upper spiral contacts 24A provided on the front surface of the relay board 20 can be reliably inserted into the multiple small holes 31 formed in the guide member 30.

In the socket 10, the connection board CB is loaded from the back surface of the frame body 10A. In particular, the guide member 30 of the connection board CB is inserted to the opening 11a from the back surface of the frame body 10A, and loaded into the area surrounded by the positioning corners 14, 14, 14, 14.

At this time, when the relay board 20 of the connection board CB is to be loaded to the depressed portion 10B provided at the back surface of the bottom of the socket 10, the bosses 10a formed at the depressed portion 10B are inserted to the positioning holes 27 of the relay board 20.

A diameter of the positioning holes 27 is formed to be larger than a diameter of the legs 10a2 serving as the base ends of the bosses 10a, but be slightly smaller than a diameter of the first retainers 10a1.

When the positioning holes 27 are forcibly fitted onto the first retainers 10a1, the first retainers 10a1 pass through the positioning holes 27, and then reach the legs 10a2 of the bosses 10a. After the positioning holes 27 reach the legs 10a2, the first retainers 10a1 retain the positioning holes 27. Hence, the relay board 20 can be held within the depressed portion 10B (see FIG. 4).

At this time, the relay board 20 is freely movable along the legs 10a2 of the bosses 10a, in the Z direction within the lengths of the legs 10a2.

It is noted that when edges of the positioning holes are covered with metal such as copper, the positioning holes 27 can be tightly fitted onto the first retainers 10a1. This configuration is preferable because the effect of preventing detachment-stop can be enhanced.

In this state, the individual upper spiral contacts 24A provided on the front surface of the relay board 20 are respectively inserted into the individual small holes 31 formed in the guide member 30. Since the inclined surfaces 31b are formed at the lower ends of the small holes 31, the upper spiral contacts 24A can be reliably guided into the small holes 31.

Also, when thin tip end portions, such as tip ends of pens or forceps, are inserted into the cut portions 11b, 11b and pushed in a direction from the front surface toward the back surface, a part of the sheet 21 forming the relay board 20 can be pressed in the Z2 direction in the drawing by way of the tip end portions. Accordingly, the positioning holes 27 formed in the sheet 21 of the relay board 20 can be moved from the legs 10a2 toward the first retainers 10a1 along the bosses 10a, and pass through the first retainers 10a1. Thus, the connection board CB can be easily detached from the bottom of the socket 10. In particular, the first retainers 10a1 detachably retain the relay board 20 to the depressed portion 10B, and the connection board CB including the relay board 20 and the guide member 30 can be easily replaced merely by lightly pushing the cut portions 11b, 11b with pens or forceps.

Referring to FIGS. 1 and 2, second retainers 10b, 10b are formed to protrude from both lateral surfaces of the frame body 10A in the Y1 and Y2 directions in the drawings toward the Z2 direction in the drawings. Referring to FIG. 4, retaining holes 41, 41, defining portions to be retained, are formed in the burn-in board 40. When the second retainers 10b, 10b are inserted into the retaining holes 41, 41, and retained, the socket 10 is fixed on the burn-in board 40.

Hence, when a facing distance between the second retainers 10b, 10b is reduced, and the second retainers 10b, 10b are detached from the retaining holes 41, 41, the socket 10 can be easily detached from the burn-in board (board) 40. That is, the second retainers 10b, 10b detachably retain the frame body 10A to the burn-in board (board) 40.

Multiple lands 42 corresponding to the multiple lower spiral contacts 24B provided on the lower surface of the relay board 20 are formed on the burn-in board 40. When the winding ends 24c at the tip ends of the lower spiral contacts 24B are pressed with the lands 42, the lands 42 and the lower spiral contacts 24B are electrically conductively connected to each other, respectively.

Patterned lines (not shown) are arranged for the individual lands 42, so that the individual lands 42 and a circuit (not shown) externally provided at the burn-in board 40 are electrically connected to each other via the patterned lines. Accordingly, the electronic component 1 can be electrically inspected while the electronic component 1 is loaded into the socket 10.

Also, referring to FIG. 4, clearance holes 44, 44 are formed in four corner portions of the burn-in board 40, in an area outside an area where the lands 42 are formed. The clearance holes 44, 44 allow the first retainers 10a1, 10a1, to be inserted thereto when the socket 10 is attached on the burn-in board 40. Hence, the socket 10 can be fixed on the burn-in board 40 even when the relay board 20 is held between the depressed portion 10B and the burn-in board 40.

If it is determined that when a plate thickness h of the relay board 20 is larger than a depth d of the depressed portion 10B (d<h), the relay board 20 can by tightly fixed between the depressed portion 10B and the burn-in board 40 when the socket 10 is attached on the burn-in board 40. In this case, the contact between the spiral contacts 24B and the lands 42 can be reliably provided.

Next, an operation of the connection board CB is described.

The connection board CB is attached to the socket 10 from the back surface thereof, and the guide member 30 is elastically supported at the opening 11a of the loading portion 11 in a biased manner with the leaf springs 25. In this state, the individual upper spiral contacts 24A provided on the front surface of the relay board 20 are respectively inserted into the individual small holes 31 formed in the guide member 30.

The electronic component 1 is loaded within the loading portion 11 with the connection surface 1A facing the guide member 30. As descried above, the electronic component 1 is loaded while both the arms 12a, 12a are lifted upward in the drawing (Z1 direction) against the biasing forces of the biasing members.

At this time, the ball contacts 2a of the electronic component 1 are arranged to face the multiple small holes 31 and the positioning small holes 31A formed in the guide member 30 in one by one correspondence.

The four corners of the electronic component 1 are guided along the tapered surfaces 14a of the positioning corners 14. Hence, the electronic component 1 can be substantially positioned within the area surrounded by the positioning corners 14, 14, 14, 14.

However, external dimensions of the electronic component 1 include an error. If the electronic component 1 is positioned using a lateral surface thereof as a reference, in some cases, the multiple ball contacts 2a do not completely face the small holes 31. Thus, a slight margin is formed between lateral surfaces of the electronic component 1 and the positioning corners 14, 14, 14, 14. The electronic component 1 is slightly movable in the X and Y directions in the drawing within the margin accordingly.

Here, FIG. 10A illustrates a state immediately after the electronic component 1 is loaded in the loading portion 11. In this state, the electronic component 1 is displaced in a direction parallel to the XY plane within the margin. The ball contacts 2a do not completely face the small holes 31.

When the lifting forces to both the arms 12a, 12a are released, both the arms 12a, 12a are rotated inward with the biasing forces of the biasing member (not shown), and the upper surface of the electronic component 1 is pressed downward in the drawing with the pair of pressing members 12c, 12c, the electronic component 1 is moved downward in the drawing (Z1 direction) as shown in FIG. 10B. Hence, the ball contacts 2a can be guided into the small holes 31 via the inclined surfaces 31a. At the same time, the electronic component 1 is moved along a direction parallel to the XY plane in the drawing, in a direction to cause the displacement occurring between the individual ball contacts 2a and the individual small holes 31 to be reduced.

Then, referring to FIG. 10C when the electronic component 1 is further pressed in the Z2 direction, the displacement can be further reduced. In addition, the ball contacts 2a can be elastically connected to the winding ends 24c at the tip ends of the upper spiral contacts 24A within the small holes 31.

As described above, it is noted that the diameter of the four positioning small holes 31A formed in the corner portions of the guide member 30 is smaller than the diameter of the residual multiple small holes 31. Hence, the electronic component 1 can be positioned to the guide member 30 with reference to the positioning small holes 31A provided at the corner portions. Accordingly, the displacement between the individual ball contacts 2a and the individual small holes 31 can be minimized. Thus, the multiple small holes 31 formed at positions other than the corner portions and the multiple ball contacts 2a provided in the area other than the corner portions can be highly accurately face each other.

Thus, merely by loading the electronic component 1 in the loading portion 11, the individual ball contacts 2a and the individual upper spiral contacts 24A can be guided to the small holes 31 from both sides in the plate-thickness direction. The ball contacts 2a can reliably contact (be conductively connected to) the upper spiral contacts 24A in the small holes 31.

In the above-described embodiment, while the description is based on the case in which the positioning small holes 31A having the smaller diameter are formed in the four corner potions of the guide member 30 in order to increase the positioning accuracy between the ball contacts 2a of the electronic component 1 and the small holes 31 of the guide member 30, the present invention is not limited thereto. The positioning small holes 31A may not be formed in the four corner portions. The expected objects can be attained as long as positioning small holes are formed in at least two or more, preferably three or more corner portions.

Also, in the above-described embodiment, while the description is based on the configuration in which the holding mechanisms 12, 12 for holding the electronic component within the loading portion are integrally provided at the frame body 10A, the present invention is not limited thereto. Holding mechanisms 12, 12 may be provided separately from a frame body 10A. For example, a configuration may be employed in which a cap body having a size equivalent to a size of a burn-in board 40 is provided, electronic components 1 loaded in multiple sockets 10 are provided on the burn-in board 40, and the sockets 10 are pressed and held with the cap body when the cap body is mounted on the burn-in board 40 and locked with the burn-in board 40.

Meanwhile, the guide member 30 employs an injection molding method in which the main body having the small holes 31 is integrally formed with the frame portion provided on the periphery of the main body. However, this method has a limitation to an increase in processing accuracy of the small holes 31.

Also, the pitch and hole diameter of the plurality of small holes 31, or the shape and size of the through holes 30B depend on the specification of the electronic component 1 such as a semiconductor. Hence, every time when the specification is changed, the main body has to be changed in layout (change in design). In contrast, the specification of the frame portion is infrequently changed as compared with the change of the main body. Thus, to form the guide member 30 by the injection molding method, a new mold having a change only in the main body has to be manufactured every time when the layout of the electronic component 1 is changed. It is difficult to reduce the manufacturing cost.

Regarding this, a guide member and a manufacturing method thereof are described below, whereby an accuracy of the small holes can be increased and an increase in the manufacturing cost can be reduced even when the layout of the electronic component 1 is changed.

FIG. 11 illustrates plan views showing another embodiment of the guide member, in which FIG. 11A is a plan view showing a main body of the guide member having a plurality of small holes formed therein, and FIG. 11B is a plan view showing the guide member with a frame attached on a periphery of the main body. FIG. 12 is a perspective view partially showing the guide member in FIG. 11. FIGS. 13A to 13G are step diagrams briefly showing respective steps of a manufacturing method of the guide member.

Referring to FIGS. 11A and 11B, a guide member 50 according to this embodiment is formed of a main body 51 having a plurality of small holes 51a, and a frame 55 attached on the periphery of the main body 51.

The main body 51 is made of metal such as nickel in a square shape, and has a through hole 51B having a smaller square shape than the main body 51, at a center portion of the main body 51. For example, a plate thickness of the main body 51 is about 0.15 mm. The plurality of small holes 51a are arranged in a matrix form within an area having a “square ring” form in plan view between an outer peripheral edge of the main body 51 and an inner peripheral edge where the through hole 51B is formed. Pitches of the small holes 51a in the vertical and horizontal directions are uniform, and a dimension thereof is about 1 mm.

The frame 55 is made of synthetic resin, and is integrally provided at the outer periphery of the main body 51. A plate thickness of the frame 55 is about 0.5 mm.

In this embodiment, nine positioning small holes 51a arrayed in three rows and three columns (3×3) are provided at each of four corner portions on an inner edge side of the frame 55, so as to interpose the small holes 31 of the main body 51 in the vertical direction. The positioning small holes 51A and the small holes 31 communicate with each other in a plate-thickness direction. A diameter of the positioning small holes 51A is slightly larger than that of the small holes 31 of the main body 51. Also, the positioning small holes 51A are formed to be inclined from the positioning small holes 51A to the small holes 31 in a tapered manner. Hence, the ball contacts 2a arranged at the four corner portions of the electronic component 1 can be easily guided to the small holes 31 of the main body 51 via the positioning small holes 51A.

The guide member 50 of this embodiment is made of metal. The diameter and pitch of the small holes 51a are formed highly accurately as compared with the small holes 31 of the guide member 30 made of resin (described above). Hence, the positions of the ball contacts 2a of the electronic component 1 can be aligned with the positions of the small holes 51a of the guide member 50 without the configuration like the guide member 30 in which the diameter of the positioning small holes 31A is formed smaller than that of the residual small holes 31. Similarly, the positioning between the small holes 51a of the guide member 50 and the upper spiral contacts (elastic contacts) 24A of the relay board 20 can be reliably performed. In particular, the ball contacts 2a of the electronic component 1 provided on one side can contact (be conductively connected to) the upper spiral contacts (elastic contacts) 24A of the relay board 20 provided on the other side via the small holes 51a of the guide member 50.

Hereinafter, the manufacturing method of the main body 51 is described.

Referring to FIG. 13A, in a first step, a substrate 61 for forming the main body 51 of the guide member 50 is prepared, and a resist layer 62 made of a photosensitive material is formed on a surface of the substrate 61 by a predetermined film thickness.

Referring to FIG. 13B, in a second step, a form pattern 51′ of the main body 51 is formed in the resist layer 62. For example, the form of the main body 51 can be patterned by covering the surface of the resist layer 62 with a mask provided over the main body 51, exposing the resist layer 62 with ultraviolet or the like emitted from above the mask, thereby photosensitizing the resist layer 62, and then performing development processing.

It is noted that the exposure method provided herein is not limited to the method using the mask. For example, an etching method using a laser lithography apparatus that directly irradiates the resist layer 62 with ultraviolet, and performs etching at a high speed for exposure.

Then, referring to FIG. 13C, in a third step, a removing layer 63 is formed on the substrate 61 in which the form pattern 51′ of the main body 51 is formed. The removing film 63 preferably employs a removing film made of an oxidized substance. For example, the removing film 63 is more preferably made of ZnO. ZnO easily causes the metal plating layer to be removed from the ZnO film even when a metal plating layer made of metal, such as Cu, Ni, or Au is provided on the ZnO film. ZnO can be easily handled, and hence, a reduction in a production cost for the formation of the main body 51 can be further promoted.

Referring to FIG. 13D, in a fourth step, plating 65 is applied onto the removing film 63 to form the main body 51. The plating 65 may be electroless plating or electrolytic plating.

Referring to FIG. 13E, in a fifth step, the resist layer 62 is removed by using an alkaline solution, and the main body 51 is separated from the substrate 61. It is noted that since the main body 51 is formed on the removing layer 63, the main body 51 can be easily separated.

Further, referring to FIG. 13F, in a sixth step, insulating paint is sprayed onto the main body 51 from the front surface or the back surface thereof by using a spray gun or the like, so as to apply insulating coating onto the entire surface of the main body 51. Accordingly, the entire surface forming the main body 51, i.e., the front and back surfaces of the main body 51 and the inner surfaces of the small holes 31 can be covered with an insulating layer 66. The insulating paint may employ, for example, hard acrylic resin paint (product name=Ohmac No. 200). The insulating paint is preferably mixed with a colorant so as to easily notice the presence of the paint.

With the above steps, the main body 51 is completed (see FIG. 11A, FIG. 13F).

Then, in a manufacturing step of forming a frame, first, the main body 51 is set at a predetermined position between a male mold and a female mold forming a mold (not shown). The mold has a cavity (not shown) at a portion corresponding to the periphery of the main body 51.

Then, synthetic resin (melted resin) which is heated and fluidized is injected with a pressure into the cavity of the closed mold. The melted resin is set in the mold, and hence, the frame 55 having a predetermined shape is integrally formed on the periphery of the main body 51. Finally, with removal from the mold, the guide member 50 in which the main body 51 and the frame 55 are integrally formed is completed (see FIG. 11B, FIG. 13G).

In addition, referring to FIG. 11A, positioning reference holes 51C, 51C are integrally formed in an edge portion near the outer periphery of the main body 51 (in FIG. 11A, at two positions). Protrusions corresponding to the reference holes 51C, 51C are formed in the cavity, and accordingly, the main body 51 can be positioned within the mold. Hence, a mounting accuracy of the frame 55 to the main body 51 can be increased. Thus, even though the plurality of recesses 32 and the supporting protrusions (supporting mechanisms) 33 (see FIG. 5) of the above-described guide member 30 are integrally formed with the frame 55 to serve as recesses 52 and supporting protrusions (supporting mechanisms) 53 when the frame 55 is to be formed, a processing accuracy can be maintained (see FIG. 11B).

With the above-described guide member 50, the main body 51 which is frequently changed in layout as a result of a change in specification of the electronic component 1, and the frame 55 which is hardly changed in layout can be manufactured in separate steps. Accordingly, when the specification of the electronic component 1 is changed, only the main body 51 can be formed on the basis of the changed specification, and the frame 55 can be manufactured on the basis of the original specification with no change applied.

That is, with the guide member 50 according to the invention of the subject application, the frame 55 which is hardly changed in layout can be commonly used. Since only the main body 51 with the layout changed is newly manufactured, the manufacturing cost can be reduced.

In addition, since the main body 51 is manufactured by resist application and plating, the main body 51 can be highly accurately formed as compared with the injection molding method. As described above in the manufacturing method, the present invention does not have to use a specified mold for manufacturing the main body 51. Therefore, even when the main body 51 is changed in layout, the main body 51 can be formed with a low manufacturing cost.

### BRIEF DESCRIPTION OF DRAWINGS

FIG. 1 is a perspective view showing a socket for holding an electronic component when viewed from above the socket according to an embodiment of the present invention.

FIG. 2 is a perspective view showing the socket in FIG. 1 from below the socket.

FIG. 3 is a plan view of the socket.

FIG. 4 is a cross section showing a configuration of the socket.

FIG. 5 is a perspective view showing a relay board and a guide member.

FIG. 6 is a plan view of the relay board.

FIG. 7 is an enlarged cross section showing a part of the relay board.

FIG. 8 is an enlarged plan view partially showing the guide member.

FIG. 9 is a perspective view showing a state in which a biasing member of the relay board is inserted into a recess of the guide member.

FIG. 10 illustrates cross sections, in which A indicates a state immediately after the electronic component is mounted on the guide member, B indicates a state in which the electronic component is being moved on the guide member after A, and C indicates a state in which mounting of the electronic component is completed.

FIG. 11A is a plan view showing a main body in which a plurality of small holes are formed according to another embodiment of a guide member.

FIG. 11B is a plan view showing the guide member with a frame attached on the periphery of the main body.

FIG. 12 is a perspective view partially showing the guide member in FIG. 11.

FIG. 13A is a step diagram briefly showing a manufacturing method of the guide member.

FIG. 13B is a step diagram briefly showing the manufacturing method of the guide member subsequent to FIG. 13A.

FIG. 13C is a step diagram briefly showing the manufacturing method of the guide member subsequent to FIG. 13B. FIG. 13D is a step diagram briefly showing the manufacturing method of the guide member subsequent to FIG. 13C.

FIG. 13E is a step diagram briefly showing the manufacturing method of the guide member subsequent to FIG. 13D.

FIG. 13F is a step diagram briefly showing the manufacturing method of the guide member subsequent to FIG. 13E.

FIG. 13G is a step diagram briefly showing the manufacturing method of the guide member subsequent to FIG. 13F.

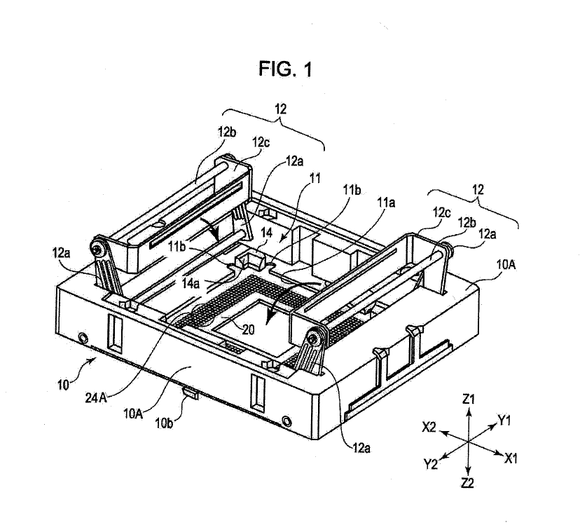

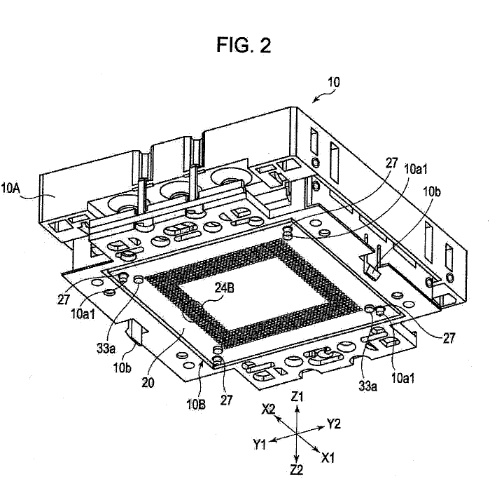

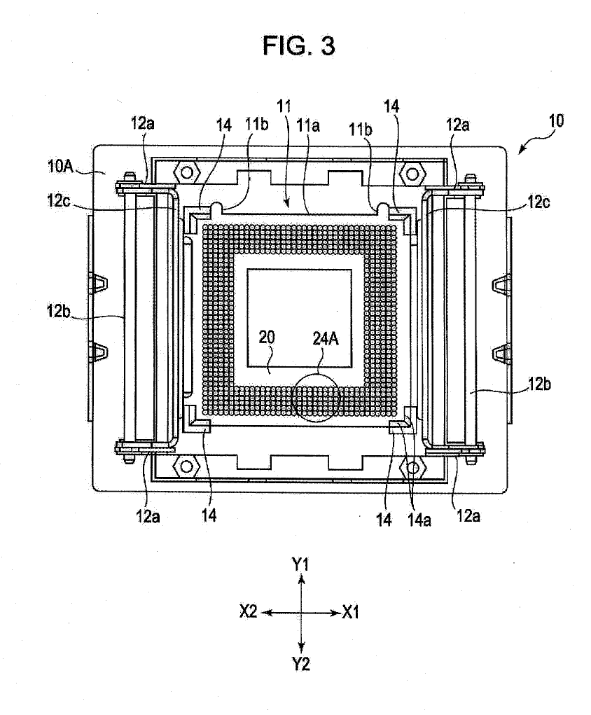

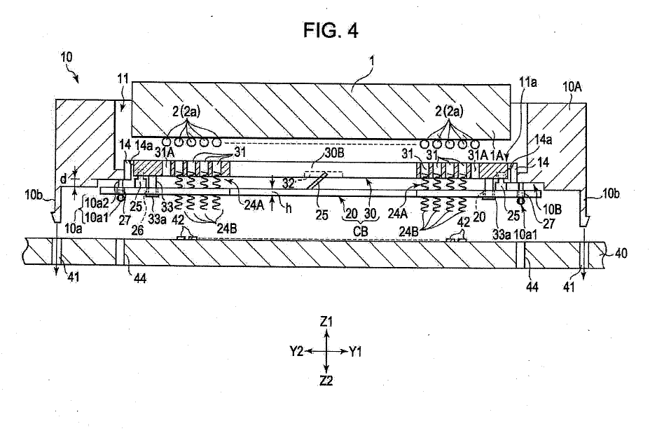

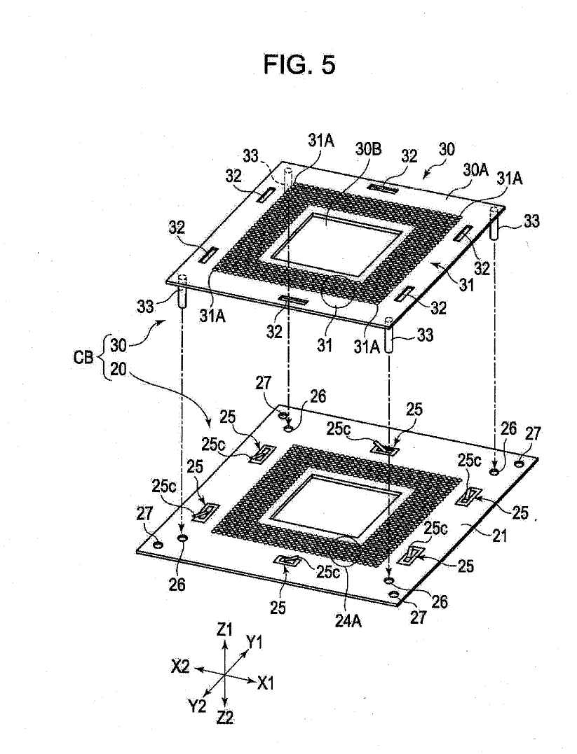

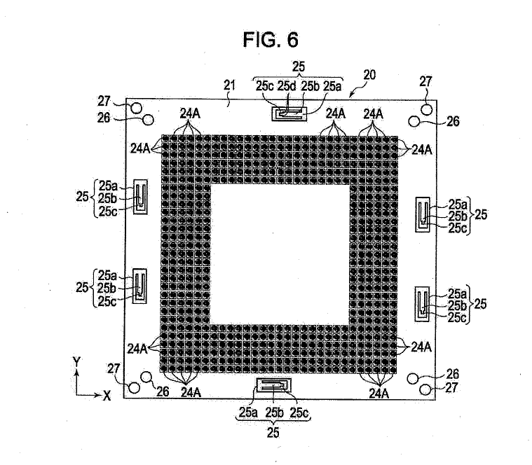

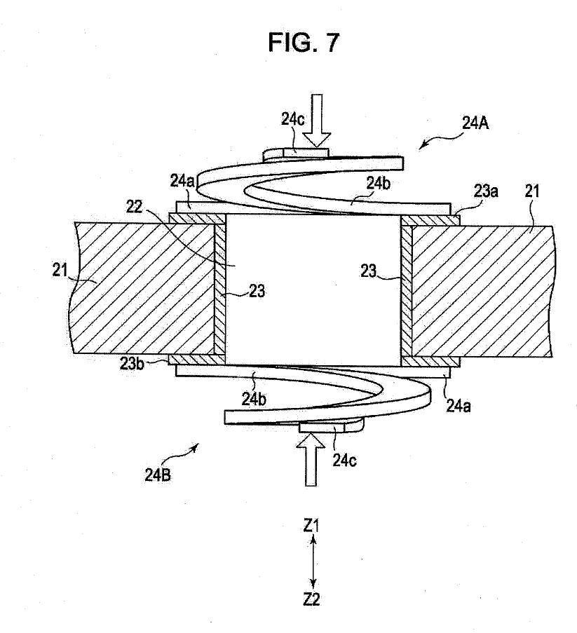

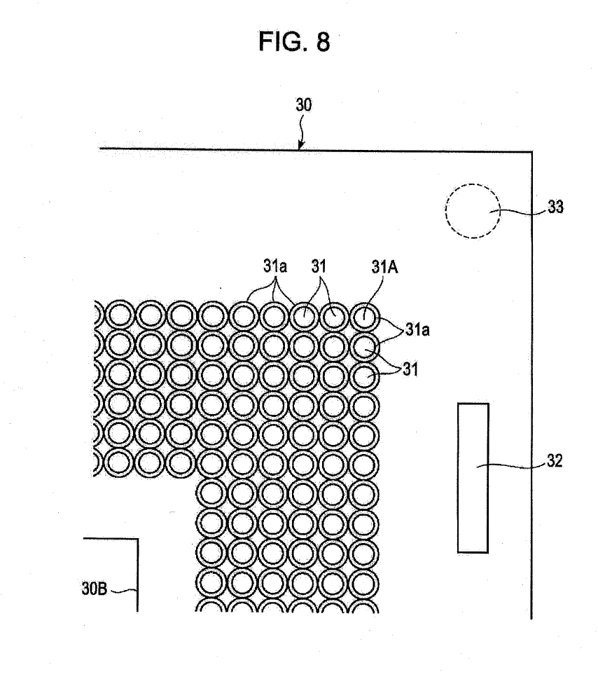

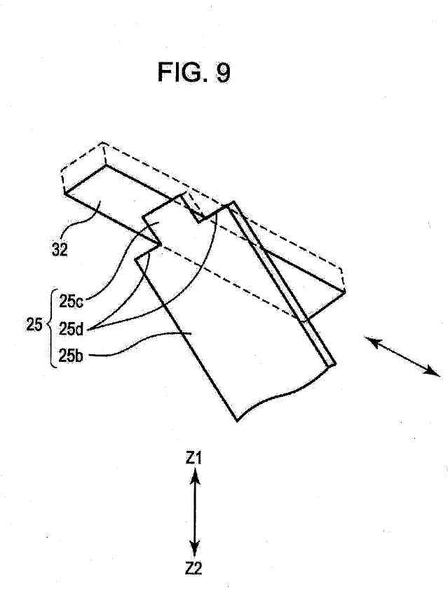

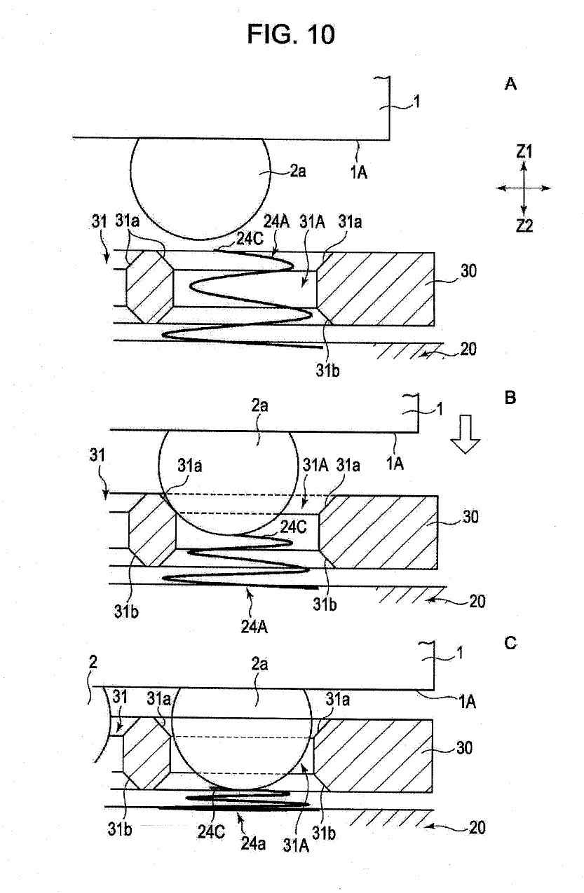

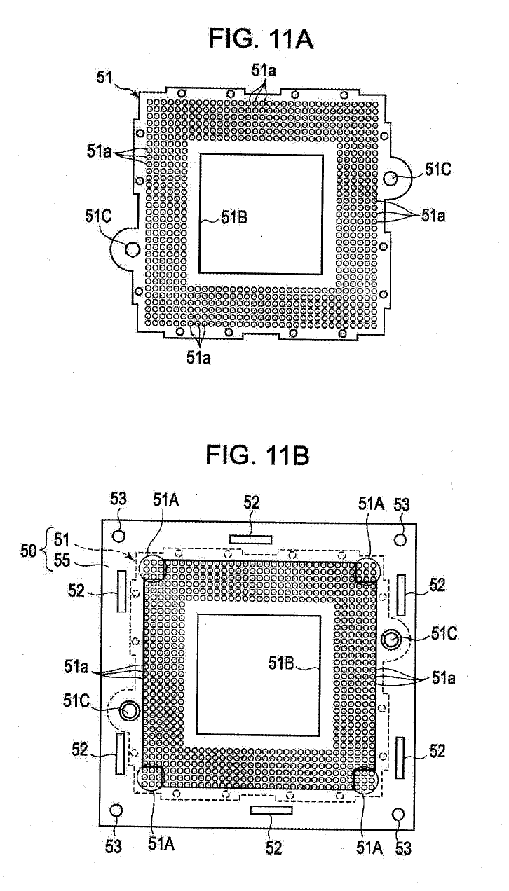

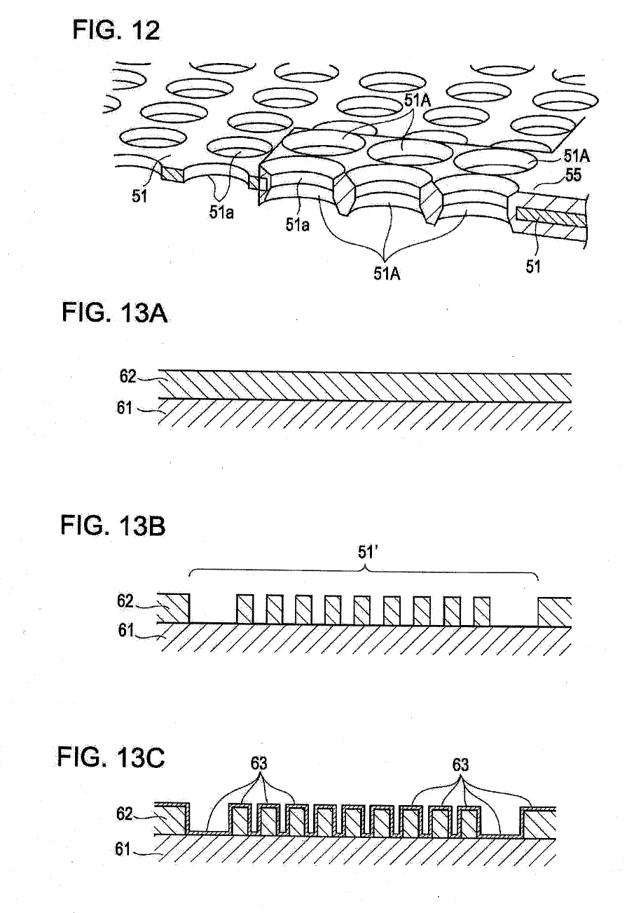

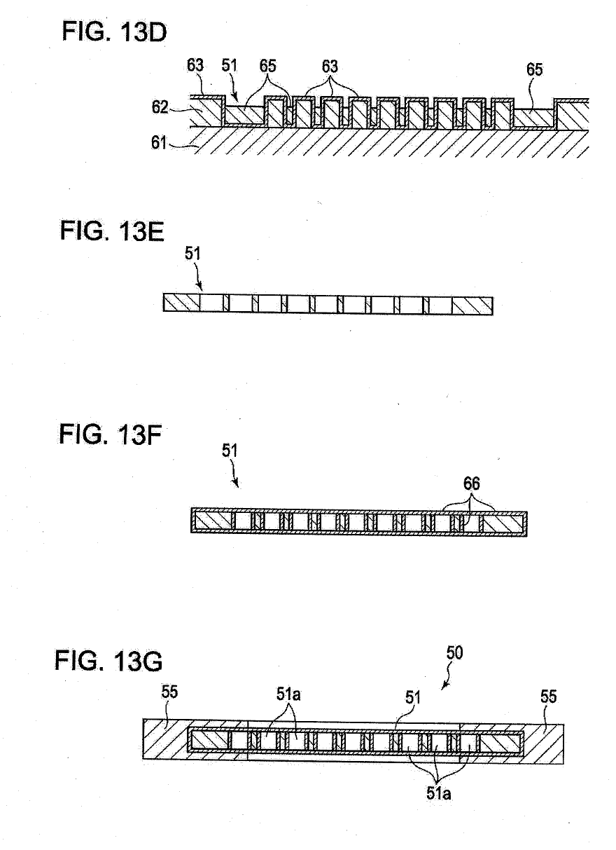

### REFERENCE NUMERALS

1 electronic component
2a ball contact (external contact)
10 socket
10A frame body
10B depressed portion
10a boss
10a1 first retainer
10a2 leg
10b second retainer
11 loading portion
11a opening
12 holding mechanism
12a arm
12c pressing member
14 positioning corner
20 relay board
21 sheet
22 through hole
24A upper spiral contact (elastic contact)
24B lower spiral contact (elastic contact)
25 leaf spring (biasing member)
25a base portion
25b elastic portion
25c protrusion
25d shoulder
26 through hole
27 positioning hole
30, 50 guide member
30A base
31, 51 small hole
31A, 51A positioning small hole
32, 52 recess
33, 53 supporting protrusion (supporting mechanism)
33a stopper means
40 burn-in board (board)
41 retaining hole
42 land
51C reference hole
55 frame
61 substrate
62 resist layer
63 removing layer
65 plating
66 insulating layer
CB connection board

1. A connection board including a relay board having a plurality of spiral contacts provided on both surfaces of the relay board, and a guide member having a plurality of small holes into which the spiral contacts and a plurality of external contacts provided on an electronic component are respectively inserted from both sides of the guide member in a plate-thickness direction, the relay board and the guide member being arranged to face each other,
wherein positioning small holes are arranged in at least two or more corner portions of the guide member together with the plurality of small holes, and a diameter of the positioning small holes is formed smaller than a diameter of the residual plurality of small holes.

2. The connection board according to claim 1, wherein an inclined surface is formed in at least one of edge portions in the plate-thickness direction of each of the small holes.

3. A connection board including a relay board having a plurality of spiral contacts provided on both surfaces of the relay board, and a guide member having a plurality of small holes into which the spiral contacts and a plurality of external contacts provided on an electronic component are respectively inserted from both sides of the guide member in a plate-thickness direction, the relay board and the guide member being arranged to face each other,
wherein a supporting mechanism and a biasing member are provided between the relay board and the guide member, the supporting mechanism supporting the guide member and the relay board such that a facing distance therebetween is changeable in a facing direction in which the guide member and the relay board move close to or away from each other, the biasing member biasing the relay board and the guide member in the facing direction and allowing the relay board and the guide member to move in a direction orthogonal to the facing direction.

4. The connection board according to claim 3, wherein the biasing member is a leaf spring having a base portion fixed to a pedestal, an elastic portion extending from the base portion, and a protrusion formed at a tip end of the elastic portion, the leaf spring being formed at the relay board.

5. The connection board according to claim 3, wherein the guide member has a recess into which the protrusion is inserted.

6. The connection board according to claim 5, wherein a width of the recess is larger than a width of the protrusion, and is smaller than a width of the base portion.

7. The connection board according to claim 5, wherein the recess is a long groove or a long hole having a longitudinal direction parallel to one of sides of the guide member.

8. The connection board according to claim 3, wherein each of the spiral contacts and the leaf spring are formed in a single manufacturing step.

9. A guide member in which a plurality of small holes are arrayed,
wherein positioning small holes are arranged in at least two or more corner portions together with the plurality of small holes, and a diameter of the positioning small holes is smaller than a diameter of the residual plurality of small holes.

10. The guide member according to claim 9, wherein an inclined surface is formed in at least one of edge portions in the plate-thickness direction of each of the small holes.

11. The guide member according to claim 9, wherein a recess is formed near one of sides of the guide member, the recess being a long groove or a long hole having a longitudinal direction parallel to the side.

12. The guide member according to claim 9, wherein a plurality of small holes are formed in a main body made of metal, and a frame made of resin is provided on a periphery of the main body.

13. A manufacturing method of a guide member including a main body having a plurality of small holes formed therein and a frame for holding a periphery of the main body, the method comprising:
(a) a step of forming a resist layer on a surface of a substrate;
(b) a step of forming a pattern of the main body form in the resist layer;
(c) a step of forming the main body within the pattern of the main body form remaining in the resist layer;
(d) a step of removing the resist layer;
(e) a step of applying insulating coating on an entire surface of the main body; and
(f) a step of forming the frame on the periphery of the main body.

14. The manufacturing method of the guide member according to claim 13, wherein in the step (b), the pattern of the main body form is formed in the resist layer by covering the resist layer with a predetermined mask, and performing exposing, photosensitizing, and developing.

15. The manufacturing method of the guide member according to claim 13, wherein in the step (b), the pattern of the main body form is formed by irradiating the resist layer with ultraviolet and etching the pattern of the main body form.

16. The manufacturing method of the guide member according to claim 13, the step (c) further including:
(g) a step of forming a base layer on surfaces of the substrate and the pattern of the main body form; and
(h) a step of forming the main body within the pattern of the main body form by plating.

17. The manufacturing method of the guide member according to claim 13, wherein in the step (e), the insulating coating is performed by spraying insulating paint.

18. The manufacturing method of the guide member according to claim 13, the step (f) further including:
(i) a step of setting the main body within a predetermined mold;
(j) a step of injecting melted resin to the periphery of the main body in the mold;
(k) a step of setting the melted resin, thereby integrally forming the frame on the periphery of the main body; and
(l) a step of removal from the mold.
